(19) United States
(12) Patent Application Publication
(10) Pub. No.: US 2026/0104478 A1
(43) Pub. Date: Apr. 16, 2026

(54) TMR SENSOR HAVING ANTIFERROMAGNETICALLY COUPLED VORTICES

(71) Applicant: Allegro MicroSystems, LLC, Manchester, NH (US)

(72) Inventors: Paolo Campiglio, Arcueil (FR); Noémie Belin, Villejuif (FR); Samridh Jaiswal, London (GB); Maxime Rioult, Massy (FR)

(73) Assignee: Allegro MicroSystems, LLC, Manchester, NH (US)

(21) Appl. No.: 18/915,521

(22) Filed: Oct. 15, 2024

(51) Int. Cl. G01R 33/09; H01F 10/32; H10N 50/01; H10N 50/10

(52) U.S. Cl. CPC G01R 33/098; G01R 33/093; H01F 10/325; H01F 10/3272; H10N 50/01; H10N 50/10

(57) ABSTRACT

Methods and apparatus for a sensor having a TMR stack with first and second vortices that are antiferromagnetically coupled together in a synthetic anti-ferromagnet (SAF) arrangement to create a TMR free layer. Due to the opposite behavior of the vortices, and to the coupling which opposes them, relatively strong fields are needed to induce magnetic modifications in the free layer. With this arrangement, the free layer of the stack has relatively wide linear response.

### BACKGROUND

Magnetic field sensors are used in a variety of applications, including, but not limited to, an angle sensor that senses an angle of a direction of a magnetic field, a current sensor that senses a magnetic field generated by a current carried by a current-carrying conductor, a magnetic switch that senses the proximity of a ferromagnetic object, a rotation detector that senses passing ferromagnetic articles, for example, magnetic domains of a ring magnet or a ferromagnetic target (e.g., gear teeth) where the magnetic field sensor is used in combination with a back-biased or other magnet, and a magnetic field sensor that senses a magnetic field density of a magnetic field.

In certain applications, magnetic field sensors include magnetoresistance elements. These elements have an electrical resistance that changes in the presence of an external magnetic field. Spin valves are a type of magnetoresistance element formed from two or more magnetic materials or layers. The simplest form of a spin valve has a reference (or magnetically fixed) layer and a free layer. The resistance of the spin valve changes as a function of the magnetic alignment of the reference and free layers. Typically, the magnetic alignment of the reference layer does not change, while the magnetic alignment of the free layer moves in response to external magnetic fields.

### SUMMARY

Embodiments of the disclosure provide methods and apparatus for a sensor including a TMR stack having a free layer with first and second vortices that are antiferromagnetically coupled together in a synthetic anti-ferromagnet (SAF) arrangement. Due to the opposite behavior of the vortices, and to the coupling which opposes them, relatively strong fields are needed to induce magnetic modifications in the free layer. With this arrangement, the free layer of the stack has relatively wide linear response.

In one aspect, a device comprises: a TMR element comprising a free layer, a spacer layer, and a reference layer, wherein the free layer comprises: a first ferromagnetic layer to support a first vortex having a first chirality; a second ferromagnetic layer to support a second vortex having a second chirality that is opposite the first chirality, wherein the first and second vortices are configured to be antiferromagnetically coupled; and a spacer between the first and second ferromagnetic layers.

A device can further include one or more of the following features: the first and second vortices move in opposite directions when an applied magnetic field is present, the applied field is in plane, the reference layer comprises first and second reference layers on opposite sides of the free layer, the first and second reference layers are configured to share active junctions with the free layer, the first and second reference layers are configured for insensitivity to an applied field, the first and second reference layers are configured for sensitivity to an applied field, a thickness of the spacer is configured to provide each magnetic moment of the first vortex is lying antiparallel to the second vortex in a same planar position, the first ferromagnetic layer comprises NiFe, the first and second ferromagnetic layers comprise NiFe, and/or the spacer comprises Ru.

In another aspect, a method, comprises: forming a TMR element comprising a free layer, a spacer layer, and a reference layer, forming the free layer by: forming a first ferromagnetic layer to support a first vortex having a first chirality; forming a second ferromagnetic layer to support a second vortex having a second chirality that is opposite the first chirality, wherein the first and second vortices are configured to be antiferromagnetically coupled; and forming a spacer between the first and second ferromagnetic layers.

A method can further include one or more of the following features: the first and second vortices move in opposite directions when an applied magnetic field is present, the applied field is in plane, the reference layer comprises first and second reference layers on opposite sides of the free layer, the first and second reference layers are configured to share active junctions with the free layer, the first and second reference layers are configured for insensitivity to an applied field, the first and second reference layers are configured for sensitivity to an applied field, a thickness of the spacer is configured to provide each magnetic moment of the first vortex is lying antiparallel to the second vortex in a same planar position, the first ferromagnetic layer comprises NiFe, the first and second ferromagnetic layers comprise NiFe, and/or the spacer comprises Ru.

### BRIEF DESCRIPTION OF THE DRAWINGS

The foregoing features of this disclosure, as well as the disclosure itself, may be more fully understood from the following description of the drawings in which:

FIG. 1 is a schematic representation of an example sensor including a TMR stack having a free layer with first and second vortices that are antiferromagnetically coupled together in a synthetic anti-ferromagnet (SAF) arrangement;

FIG. 2 is schematic representation of a TMR bridge with TMR elements;

FIG. 3 is a schematic representation of a bridge resistor having TMR pillars;

FIG. 4 is a schematic representation of a MTJ with tunneling magnetoresistance;

FIG. 5A shows a schematic representation of a free layer with first and second vortices that are antiferromagnetically coupled together in a synthetic anti-ferromagnet (SAF) arrangement and FIG. 5B shows movement of the first and second vortices in response to an applied field;

FIG. 6A is a graphical representation of first and second vortices having the same chirality and direction of core displacement;

FIG. 6B is a graphical representation of first and second vortices having the opposite chirality and direction of core displacement for the free layer of FIG. 5A;

FIG. 6C shows a graphical representation of simulated results for AF coupling of −10 mJ/m², −2 mJ/m², and zero AF coupling;

FIG. 7 is an example TMR stack configuration having a free layer with first and second vortices that are antiferromagnetically coupled together in a synthetic anti-ferromagnet (SAF) arrangement;

FIG. 8A is an example TMR stack configuration having a free layer with first and second vortices that are antiferromagnetically coupled together and between first and second references layers to form two active junctions; and

FIG. 8B is an example TMR stack configuration having a free layer with first and second vortices that are antiferromagnetically coupled together and between first and second references layers to form a dead element that is not responsive to an applied field.

### DETAILED DESCRIPTION

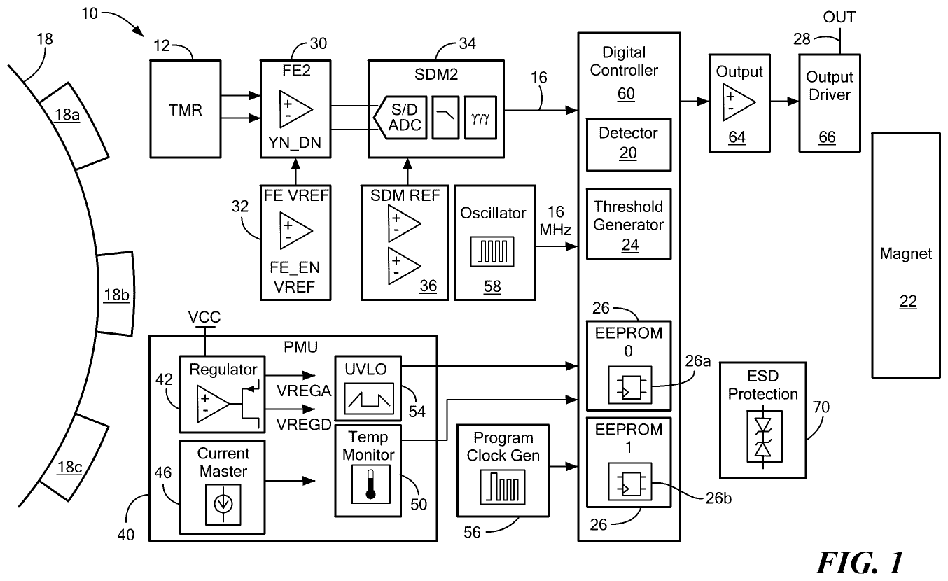

FIG. 1 shows an example magnetic field sensor 10 having at least one magnetic field sensing element 12 that includes one or more TMR elements having antiferromagnetically coupled vortices for enhancing linearity in accordance with example embodiments of the disclosure. While sensor 10 is shown as a gear tooth sensor, it is understood that a wide variety of sensor types, such as current, position, angle, speed, and other applications in which enhanced linearity is desirable, can include antiferromagnetically coupled vortices in accordance with example embodiments of the disclosure.

The sensor 10 is configured to generate a magnetic field signal 16 indicative of a magnetic field associated with a target 18 and a detector 20 responsive to the magnetic field signal and to a threshold level from a threshold generator 24 to generate a sensor output signal 28 containing transitions associated with features of the target in response to the magnetic field signal crossing the threshold level.

The target 18 can have a variety of forms, including, but not limited to a gear having gear teeth 18a-18c or a ring magnet having one or more pole pair. Also, linear arrangements of ferromagnetic objects that move linearly are possible. In the example embedment of FIG. 1, magnetic field sensor 10 may take the form of a rotation detector to detect passing gear teeth, for example, gear teeth 18a-18c of a ferromagnetic gear or, more generally, target object 18. A permanent magnet 22 can be placed at a variety of positions proximate to the gear 18, resulting in fluctuations of a magnetic field proximate to the gear as the gear rotates in a so-called “back-bias” arrangement.

Features of the target 18 are spaced from the sensing elements 12 by an airgap. Although intended to be fixed once the sensor 10 is in place in a particular application, the airgap can vary for a variety of reasons. A difference between angles of the transitions of the sensor output signal 28 and locations of the associated features 18a-18c of the target 28 is referred to as a “hard offset.”

Sensing elements 12 can take a variety of forms, such as TMR elements, as may be arranged in one or more bridge or other configurations in order to generate one or more single-ended or differential signals indicative of the sensed magnetic field. A front-end amplifier 30 can be used to process the magnetic field sensing element output signal to generate a further signal for coupling to an analog-to-digital converter (ADC) 34 as may include one or more filters, such as a low pass filter and/or notch filter, and as may take the form of a sigma delta modulator to generate a digital magnetic field signal 16. Features of the magnetic field signal processing can include a front-end reference 32 and a sigma delta reference 36.

Sensor 10 includes a power management unit (PMU) 40 as may contain various circuitry to perform power management functions. For example, a regulator 42 can output a regulated voltage for powering analog circuitry of the sensor (VREGA) and/or a regulated voltage for powering digital circuitry of the sensor (VREGD). A bias current source 46, a temperature monitor 50 and an undervoltage lockout 54 can monitor current, temperature, and voltage levels and provide associated status signals to a digital controller 60. A clock generation element 56 and an oscillator 58 are coupled to the digital controller 60.

Digital controller 60 processes the magnetic field signal 16 to determine the speed, position, and/or direction of movement, such as rotation of target 18 and outputs one or more digital signals to an output protocol module 64. More particularly, controller 60 determines the speed, position, and/or direction of target 18 based on the magnetic field signal 16 and can combine this information with fault information in some embodiments to generate the sensor output signal 28 in various formats. The output of module 64 is fed to an output driver 66 that provides the sensor output signal 28 in various formats, such as a so-called two-wire format in which the output signal is provided in the form of current pulses on the power connection to the sensor or a three-wire format in which the output signal is provided at a separate dedicated output connection. Formats of the output signal 28 can include variety of formats, for example a pulse-width modulated (PWM) signal format, a Single Edge Nibble Transmission (SENT) format, a Serial Peripheral Interface (SPI) format, a Local Interconnect Network (LIN) format, a CAN (Controller Area Network) format, an Inter-Integrated Circuit (I²C) format, or other similar signal formats. Sensor 10 can further include electrostatic discharge (ESD) protection 70.

The digital controller 60 includes detector 20, threshold generator 24, and memory 26 such as EEPROMs 26a, 26b. Memory 26 can be used to store values for various sensor functionality including storing function coefficients for use by the threshold generator 24 in generating the adaptive threshold levels for use by detector 20.

Detector 20 is coupled to receive the threshold level thus generated and the magnetic field signal 16 and compare the received levels to generate a binary, two-state, detector output signal that has transitions when the signal 16 crosses the threshold level. Movement speed of the target 18 can be detected in accordance with the frequency of the binary signal.

It should be appreciated that a direction of rotation of the target 28 may be determined in embodiments containing multiple sensing elements 12 configured to generate phase separated magnetic field signals (as are sometimes referred to as channel signals), in which case the direction of rotation can be determined based on a relative phase or relative time difference (e.g., lag or lead) of a particular edge transition of detector output signals associated with the phase separated magnetic field signals.

It is understood that embodiments of TMR-based sensing elements are useful in a wide variety of magnetic sensors. While an example sensor is shown and described above, any practical magnetic sensor in which TMR sensing elements are desirable can be provided. For example, TMR sensing elements are useful in many magnetic position and angle sensors that require high resolution. Further example sensors in which TMR-based sensing elements are shown and described below.

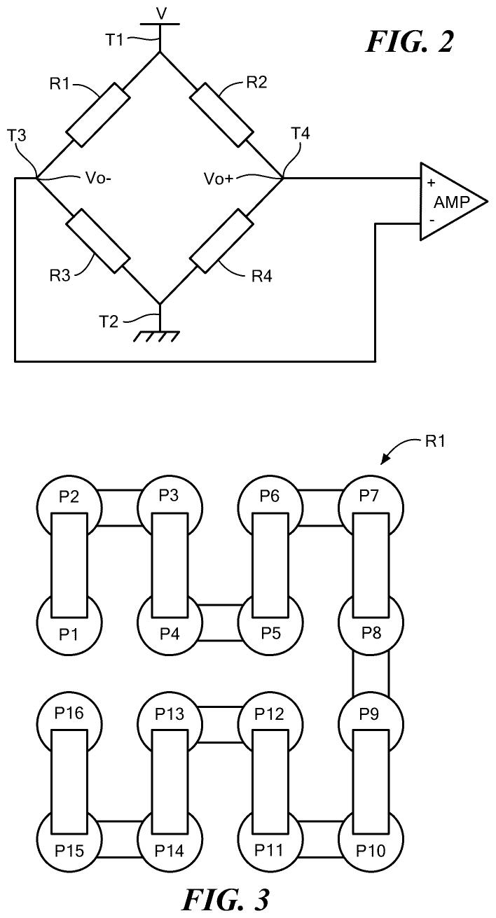

FIG. 2 shows an example TMR bridge 200 having a first resistor R1, a second resistor R2, a third resistor R3, and fourth resistor R4 coupled in a bridge configuration, which can correspond to the sensing elements 12 of FIG. 1. A first terminal T1 is coupled to a voltage supply and a second terminal T2 is coupled to ground (or other potential). A third terminal T3 provides a first differential output signal Vo− and a fourth terminal T4 provides a second differential output signal Vo+. The differential output Vo+, Vo− of the bridge can be provided to an amplifier AMP or other circuitry for processing of the output of the magnetic field sensing elements, such as described above.

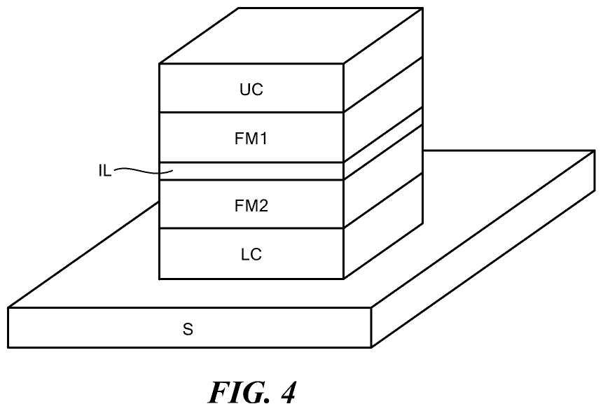

FIG. 3 shows an example implementation in which bridge resistor R1 contains sixteen pillars P1-16 that provide the total resistance for R1. It is understood that a TMR resistor that provides a leg of the bridge can comprise any practical number of pillars connected in series and/or in parallel to provide the TMR bridge resistor. Pillars can be designed to have the same or different resistances.

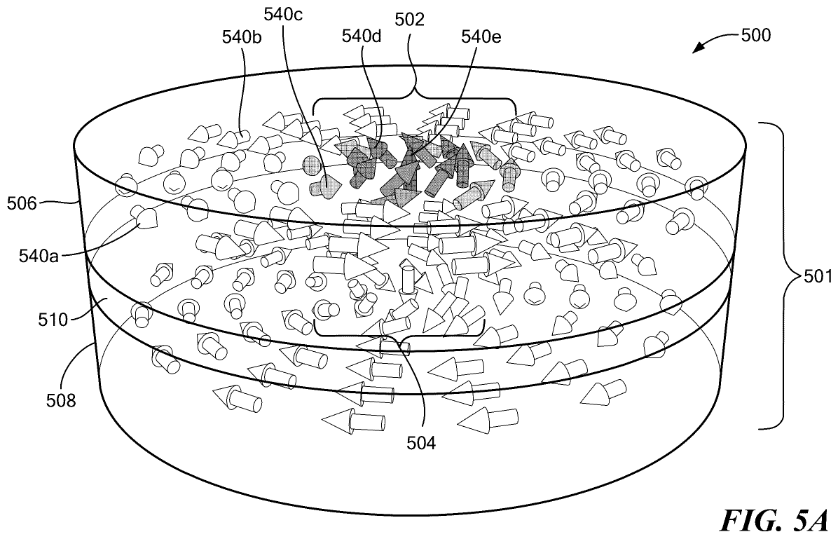

FIG. 4 shows an example magnetic tunnel junction (MTJ) that uses TMR to provide TMR elements, e.g., pillars. As is known in the art, tunneling magnetoresistance (TMR) occurs in a magnetic tunnel junction (MTJ) which has first and second ferromagnets FM1, FM2 separated by a thin insulative layer IL, such as MgO. An upper contact UC can be provided on the first ferromagnet FM1 and a lower contact LC can be provided on the second ferromagnet FM2. A substrate S can support the MTJ structure. The insulative layer should be thin, in the order of a few nanometers, so as to allow electrons to ‘tunnel’ from one of the ferromagnets to the other. It will be appreciated that this is a quantum mechanical phenomenon.

The direction of the two magnetizations of the ferromagnetic films FM1, FM2 can be switched individually by an external magnetic field. If the magnetizations are in a parallel orientation, it is more likely that electrons will tunnel through the insulating film IL than if they are in the oppositional (antiparallel) orientation. Consequently, such a junction can be switched between two states of electrical resistance, one with low resistance and one with high resistance.

It is understood that the directions of FM1 and FM2 do not necessarily have to be switched: if the external field angle is neither parallel or anti-parallel then the resulting magnetization changes as the composite angle between the external field and the reference layer. The resistance variation is proportional to the cosine of such composite angle which makes TMR elements useful for angle sensing applications.

Electrons with certain spin orientation (“spin-up” or “spin-down”) can tunnel from one ferromagnetic layer to another ferromagnetic layer through the non-conductive thin insulating layer if there are available free states with the same spin orientation. In case of the parallel state, the majority spin (“spin-up”) electrons and minority spin (“spin-down”) electrons can tunnel to the second ferromagnetic layer and fill majority (“up”) and minority (“down”) states, respectively. This will result in large conductance and corresponds to the low resistive state. In case of the anti-parallel state, the majority spin (“spin-down”) electrons and minority spin (“spin-up”) electrons from first ferromagnetic layer fill the minority (“down”) and majority (“up”) states in the second ferromagnetic layer, respectively. This will result in the low conductance and corresponds to the high resistive state. Tunneling magnetoresistance is described in J. Mathon, Theory of Tunneling Magnetoresistance, 76 PHASE TRANSITIONS 491-500 (2003), which is incorporated herein by reference.

Example embodiments of the disclosure provide methods and apparatus for a sensor having a TMR stack with first and second vortices that are antiferromagnetically coupled together in a synthetic anti-ferromagnet (SAF) arrangement to create a TMR free layer. Due to the opposite behavior of the vortices, and to the coupling which opposes them, relatively strong fields are needed to induce magnetic modifications in the free layer. With this arrangement, the free layer of the stack has relatively wide linear response.

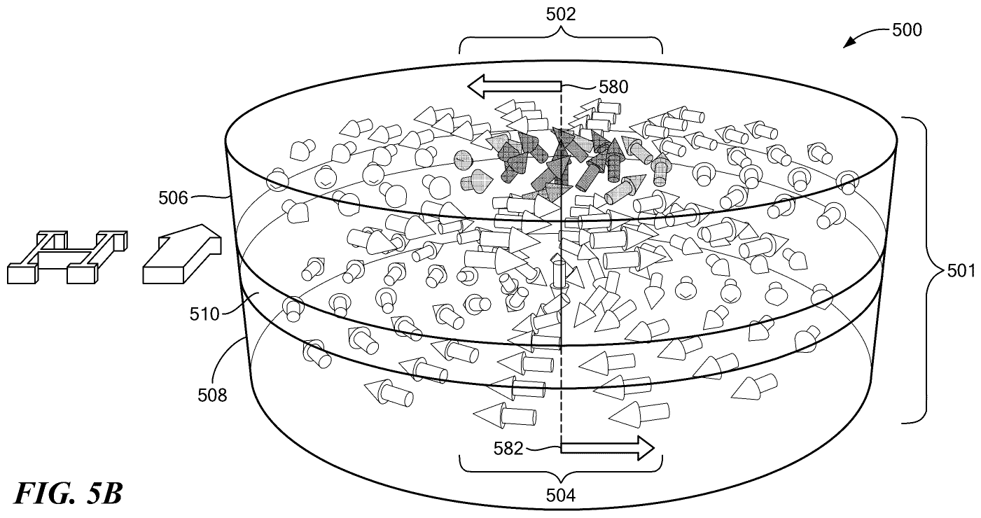

FIG. 5A is a schematic representation of an example magnetoresistance free layer 500 having a plurality of material layers stacked on top of one another and configured to have antiferromagnetically coupled first and second vortices in accordance with example embodiments of the disclosure. In embodiments, magnetoresistance elements comprises a spin valve. Spin valves minimally have three layers: a fixed (also referred to as a reference) layer having a fixed magnetic alignment, a free layer (FIG. 5A) having a magnetic alignment that changes in response to an external magnetic field and an insulating layer separating the two. When the magnetic alignment of the free layer is lined up with the magnetic alignment of the reference layer, the electrical resistance of the spin valve has a minimal value. Conversely, when the magnetic alignment of the free layer is aligned in an opposite direction to the reference layer, the electrical resistance of the spin valve is at a maximum value. At points in between, the resistance is at an intermediate value. Generally, as the magnetic alignment of the free layer changes from one extreme (e.g., oppositely aligned with the reference layer) to the other extreme (e.g., aligned with the reference layer), the electrical resistance of the spin valve changes linearly from its maximum value to its small value. The TMR element 500 can be driven with a current that flows between the bottom electrode and the cap.

FIG. 5A shows an example TMR free layer 501 with antiferromagnetically coupled first and second vortices 502, 504 in respective first and second ferromagnetic layers 506, 508 separated by a non-magnetic spacer 510. The first and second vortices 502, 504 are coupled antiferromagnetically in the same manner that ferromagnetic (FM) layers are coupled in Synthetic Antiferromagnets (SAFs). In embodiments, the free layer 501 comprises a trilayer of FM/NM/FM, where the two FM layers 506,508 are coupled with tunable sign and magnitude depending on the Non-Magnetic (NM) spacer 510 thickness due to RKKY interaction. When sufficiently thick ferromagnetic layers 506, 508 are patterned in micron-sized structures, a vortex structure is naturally adopted. In embodiments, this vortex structure is used in FM layers in SAFs. In example embodiments, in which a suitable NM layer 510 thickness is selected, each magnetic moment of one vortex is lying antiparallel to the other vortex in the same planar position.

The magnetic first vortex 502 may be formed in the first FM layer 508 of the TMR element of FIG. 4. The first vortex 502 has magnetization directions (e.g., a magnetization direction 540a, magnetization direction 540b, magnetization direction 540c, magnetization direction 540d) that loop around the free layer 501. An angle of the magnetization direction 540a with respect to a surface of the free layer 501 is about 0° at the outer edges of the free layer/first FM layer 506. The magnetic vortex 502 has a core (sometimes called a “magnetic vortex core”) having a center that is coaxial with a center of the FM vortex layer 506. The magnetization directions 540 become more and more non-planar the closer to the center of the core. That is, the angle of the magnetization direction 540 with respect to the surface of the free layer 501 increases the closer to the center of the core a magnetization direction is. For example, an angle of the magnetization direction 540b with respect to the surface of the free layer 501 is higher than the angle of the magnetization direction 540a with respect to the surface of the free layer 501, an angle of the magnetization direction 540c with respect to the surface of the free layer 501 is higher than the angle of the magnetization direction 540b with respect to the surface of the free layer 501, an angle of the magnetization direction 540d with respect to the surface of the free layer is higher than the angle of the magnetization direction 540c with respect to the surface of the free layer, and angle of the magnetization direction 540e with respect to the surface of the free layer is higher than the angle of the magnetization direction 540d. As can be seen, angle of the magnetization direction 540e approaches vertical.

It is understood that the first and second vortices 502, 504 can rotate in directions opposite to that shown in the illustrative embodiment of FIG. 5A. That is, the vortices can have opposite chirality. In addition, in other embodiments, the coupling layer can have perpendicular anisotropy in the opposite direction to that shown. That is, the polarity/orientation of the coupling layer can be “down” instead of “up.”

The second vortex 504 forms in the second FM layer 508 with chirality in the opposite direction as the first vortex 502. As can be seen, angles of magnetization in the second vortex 504 are opposite to those of the first vortex 502. In the illustrated embodiment, the angle of magnetization tend to point “up” in the center of the first vortex and the angles of magnetization tend to point “down” in the center of the second vortex. As noted above, each magnetic moment of the first vortex 502 is lying antiparallel to the second vortex 504 in the same planar position, and vice-versa.

As shown in FIG. 5B, when an external field H is applied, the magnetic moments parallel to the field are favored that results in a vortex response as a movement of its core perpendicularly to the applied field. The direction of this movement depends on the vortex chirality. In the illustrated embodiment, the first vortex 502 moves to the “left” 580 (as seen on the page) and the second vortex 504 moves to the “right” 582.

In the example vortex SAF, since two vortices 502, 504 are antiferromagnetically coupled and have opposite chiralities, the effect of the applied field causes different movement directions in each. But in order to do so, the antiferromagnetic coupling established with the RKKY is broken so that the movement of the two cores is significantly hindered. For movement to occur, it would be necessary to break the antiferromagnetic established with the RKKY (which causes every magnetic moment of one vortex lying antiparallel to the other vortex in the same planar position), so that movement of the two cores is significantly hindered. It can be noted that as the two vortices are AF coupled through RKKY, their movement amplitude is rather small; the movement of the two cores is significantly hindered as compared to no AF coupling.

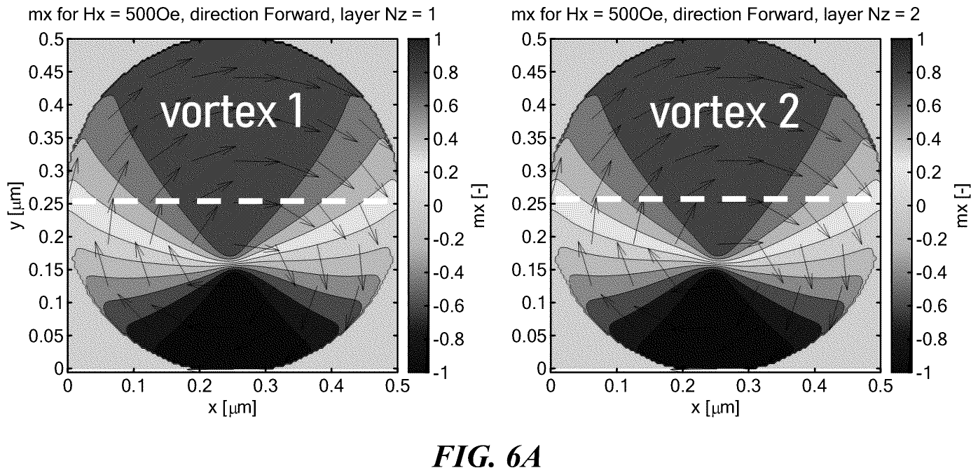

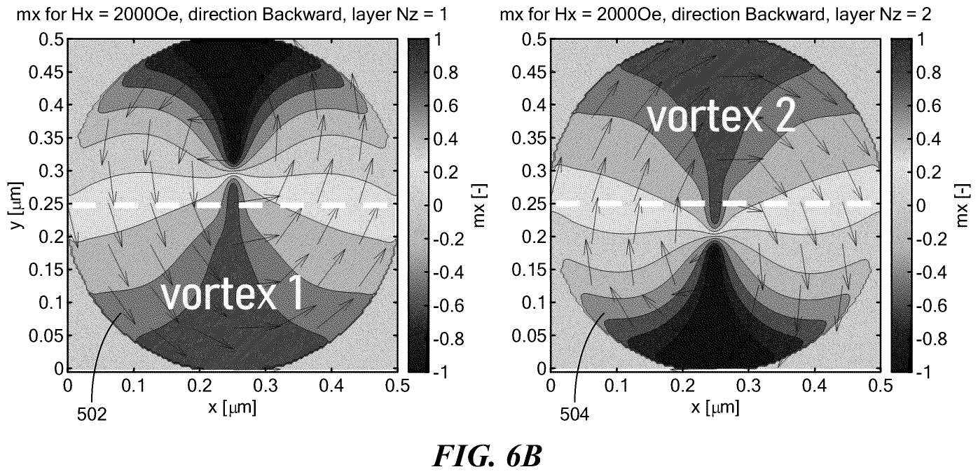

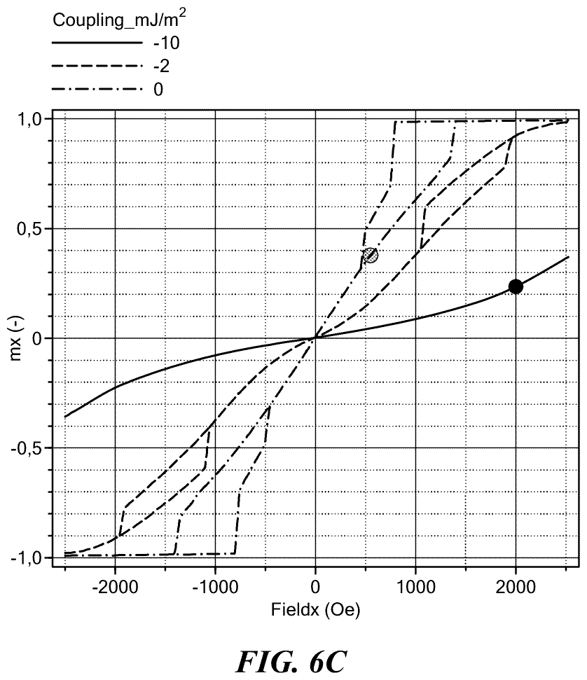

FIG. 6A shows a first vortex 1 and a second vortex 2 in x, y coordinates with movement mx for an applied field Hx of 500 Oe where each of the FM layers have the same chirality and direction of core displacement to the applied field Hx. As can be seen, the first and second vortices have similar positional characteristics. There is no AF coupling in the layers.

FIG. 6B shows represents the free layer 501 of FIG. 5 including the first vortex 502 and the second vortex 504 in x, y coordinates for movement mx with an applied field Hx=2000 Oe where each of the FM layers have the opposite chirality and direction of core displacement to the applied field Hx. As can be seen, the first and second vortices have opposite positional characteristics due to coupling of 10 mJ/M².

FIG. 6C shows a graphical representation of simulated results for AF coupling of −10 mJ/m², −2 mJ/m², and zero AF coupling. It is understood that the minus sign for −10 mJ/m² denotes antiferromagnetic coupling. As can be seen the magnetization mx vs applied field has a gentler slope for AF coupling of −10 mJ/m² than the other results. By increasing the strength of the AF coupling both the nucleation and annihilation fields increase (the fields at which a vortex is created and broken respectively clearly identified here as a jump in the response, in both positive and negative fields). Also, a certain level of non-linearity is in the low-field range of the sensor.

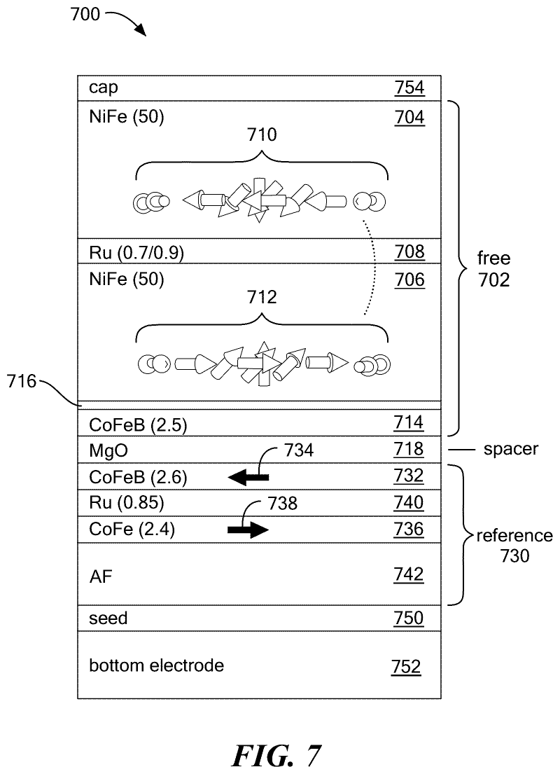

FIG. 7 shows an example stack 700 having a free layer 702 having first and second FM layers 704, 706 separated by an NM spacer 708 in accordance with the illustrative embodiment of FIG. 5A. The first FM layer 704 supports a first vortex 710 and the second FM layer 706 supports a second vertex 712. In the illustrated embodiment, the free layer 702 includes a CoFeB layer 714 and a spacer layer 716, such as Ru. Spacer layer 718, which may comprise MgO, separates the free layer 702 and a reference layer 730. In the illustrated embodiment, the reference layer 730 includes a first pinning layer 732 having a first field orientation indicated by arrow 734 and a second pinning layer 736 having a second field orientation indicated by arrow 738 for in plane sensitivity. In the illustrated embodiment, the first and second field orientations 734, 738 are opposite. The pinning layers 732, 736 are separated by a layer 740, which may comprise Ru. The reference layer 730 also includes an antiferromagnetic layer 742.

The stack 700 may also include a seed layer 750 and a bottom electrode 752, as well as a cap layer 754 on top of the free layer.

The example stack 700 may be well-suited for sensor applications having relatively wide ranges due to the difficulty in moving vortex cores in a vortex SAF, as described above.

It is understood that example materials and layer thicknesses (in nanometers) are shown in the example embodiments to facilitate an understanding of the disclosure and should not limit the invention as claimed in any way.

In embodiments, a TMR element can include a free layer having first and second active junctions in the same stack, which can be referred to as a dual junction. In one embodiment, the orientation of multiple reference layers provides an active element for sensitivity to applied fields. In other embodiments, the orientation of multiple reference layers provides a ‘dead’ element that is insensitive to applied fields since the response of the junctions cancels, e.g., nets to zero.

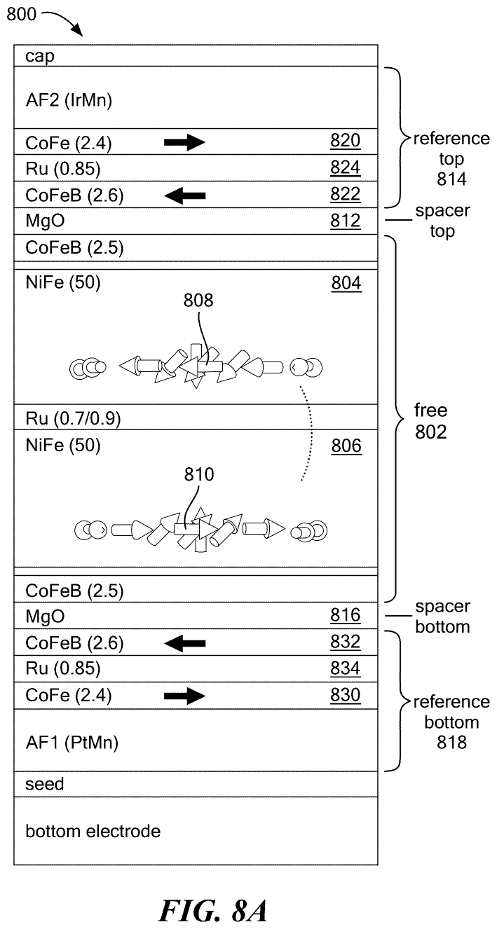

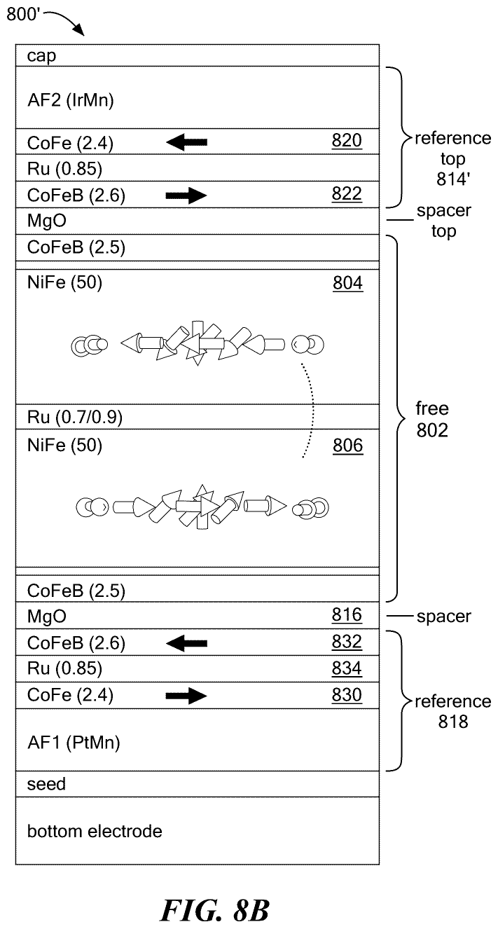

FIG. 8A shows a stack 800 having dual junctions that provide an active element where junction refers to a free layer/reference layer interface. The stack 800 includes a free layer 802 having first and second FM layers 804, 806 with respective first and second vortices 808, 810, as described above. A first spacer 812 is between the first FM layer 804 and a first reference layer 814. A second spacer 816 is between the second FM layer 806 and a second reference layer 818.

The first reference layer 814 includes a first layer 820, such as CoFe, and a second layer 822, such as CoFeB, separated by an Ru layer 824 for example. The first and second layers 820, 822 have opposite orientations, as shown. The second reference layer 818 include a first layer 830, such as CoFe, and a second layer 832, such as CoFeB, separated by an Ru layer 834 for example. The first and second layers 830, 832 have opposite orientations, as shown. The orientations of the first and second reference layers 814, 818 provide an element that is sensitive to an applied field.

FIG. 8B shows a stack 800′ that is similar to the stack 800 of FIG. 8A but with the orientations of the layers 820, 822 switched in the first reference layer. With this arrangement, the element is not responsive to an applied field since the response of the two junctions are opposite and so cancel each other, e.g., the stack 800′ provides a dead element.

In embodiments the stack 800′ is used for correction of thermal drifting. Due to their temperature coefficient, TMR elements are sensitive as magnetic fields but also to temperature variation. As such, a TMR dead element can be used to detect only temperature variation allowing to disentangle the two effects. It is understood that a TMR dead element refers to being ‘dead’ to magnetic fields.

The direction of one of the two reference layers, which may be pinned by a different AF material, can be switched locally, such as by using laser pinning, for example.

In general, magnetic materials can have a variety of magnetic characteristics and can be classified by a variety of terms, including, but not limited to, ferromagnetic, antiferromagnetic, and nonmagnetic. Description of the variety of types of magnetic materials is not made herein in detail. However, let it suffice here to say, that a ferromagnetic material is one in which magnetic moments of atoms within the ferromagnetic material tend to, on average, align to be both parallel and in the same direction, resulting in a nonzero net magnetic magnetization of the ferromagnetic material.

An antiferromagnetic material is one in which magnetic moments within the antiferromagnetic material tend to, on average, align to be parallel, but in opposite directions in sub-layers within the antiferromagnetic material, resulting in a zero net magnetization.

As used herein, the term “magnetic field sensing element” is used to describe a variety of electronic elements that can sense a magnetic field. The magnetic field sensing element can be, but is not limited to, a Hall effect element, a magnetoresistance element, or a magnetotransistor. As is known, there are different types of Hall effect elements, for example, a planar Hall element, a vertical Hall element, and a Circular Vertical Hall (CVH) element. As is also known, there are different types of magnetoresistance elements, for example, a semiconductor magnetoresistance element such as Indium Antimonide (InSb), a giant magnetoresistance (GMR) element, for example, a spin valve, an anisotropic magnetoresistance element (AMR), a tunneling magnetoresistance (TMR) element, and a magnetic tunnel junction (MTJ). The magnetic field sensing element may be a single element or, alternatively, may include two or more magnetic field sensing elements arranged in various configurations, e.g., a half bridge or full (Wheatstone) bridge. Depending on the device type and other application requirements, the magnetic field sensing element may be a device made of a type IV semiconductor material such as Silicon (Si) or Germanium (Ge), or a type III-V semiconductor material like Gallium-Arsenide (GaAs) or an Indium compound, e.g., Indium-Antimonide (InSb).

As is known, some of the above-described magnetic field sensing elements tend to have an axis of maximum sensitivity parallel to a substrate that supports the magnetic field sensing element, and others of the above-described magnetic field sensing elements tend to have an axis of maximum sensitivity perpendicular to a substrate that supports the magnetic field sensing element. In particular, planar Hall elements tend to have axes of sensitivity perpendicular to a substrate, while metal based or metallic magnetoresistance elements (e.g., GMR, TMR, AMR) and vertical Hall elements tend to have axes of sensitivity parallel to a substrate.

As used herein, the term “magnetic field sensor” is used to describe a circuit that uses a magnetic field sensing element, generally in combination with other circuits. Magnetic field sensors are used in a variety of applications, including, but not limited to, an angle sensor that senses an angle of a direction of a magnetic field, a current sensor that senses a magnetic field generated by a current carried by a current-carrying conductor, a magnetic switch that senses the proximity of a ferromagnetic object, a rotation detector that senses passing ferromagnetic articles, for example, magnetic domains of a ring magnet or a ferromagnetic target (e.g., gear teeth) where the magnetic field sensor is used in combination with a back-biased or other magnet, and a magnetic field sensor that senses a magnetic field density of a magnetic field.

Various embodiments of the concepts, systems, devices, structures and techniques sought to be protected are described herein with reference to the related drawings. Alternative embodiments can be devised without departing from the scope of the concepts, systems, devices, structures and techniques described herein. It is noted that various connections and positional relationships (e.g., over, below, adjacent, etc.) are set forth between elements in the following description and in the drawings. These connections and/or positional relationships, unless specified otherwise, can be direct or indirect, and the described concepts, systems, devices, structures and techniques are not intended to be limiting in this respect. Accordingly, a coupling of entities can refer to either a direct or an indirect coupling, and a positional relationship between entities can be a direct or indirect positional relationship.

As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s). The following definitions and abbreviations are to be used for the interpretation of the claims and the specification. As used herein, the terms “comprises,” “comprising, “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Unless otherwise specified, the term “substantially” refers to values that are within ±10%. For example, a first direction that is “substantially” perpendicular to a second direction may refer to a first direction that is within ±10% of making a 90° angle with the second direction.

Having described exemplary embodiments of the disclosure, it will now become apparent to one of ordinary skill in the art that other embodiments incorporating their concepts may also be used. The embodiments contained herein should not be limited to disclosed embodiments but rather should be limited only by the spirit and scope of the appended claims. All publications and references cited herein are expressly incorporated herein by reference in their entirety.

Elements of different embodiments described herein may be combined to form other embodiments not specifically set forth above. Various elements, which are described in the context of a single embodiment, may also be provided separately or in any suitable subcombination. Other embodiments not specifically described herein are also within the scope of the following claims.

What is claimed is:

1. A device, comprising:
a TMR element comprising a free layer, a spacer layer, and a reference layer, wherein the free layer comprises:
a first ferromagnetic layer to support a first vortex having a first chirality;
a second ferromagnetic layer to support a second vortex having a second chirality that is opposite the first chirality, wherein the first and second vortices are configured to be antiferromagnetically coupled; and
a spacer between the first and second ferromagnetic layers.

2. The device according to claim 1, wherein the first and second vortices move in opposite directions when an applied magnetic field is present.

3. The device according to claim 2, wherein the applied field is in plane.

4. The device according to claim 1, wherein the reference layer comprises first and second reference layers on opposite sides of the free layer.

5. The device according to claim 4, wherein the first and second reference layers are configured to share active junctions with the free layer.

6. The device according to claim 5, wherein the first and second reference layers are configured for insensitivity to an applied field.

7. The device according to claim 4, wherein the first and second reference layers are configured for sensitivity to an applied field.

8. The device according to claim 1, wherein a thickness of the spacer is configured to provide each magnetic moment of the first vortex is lying antiparallel to the second vortex in a same planar position.

9. The device according to claim 1, wherein the first ferromagnetic layer comprises NiFe.

10. The device according to claim 1, wherein the first and second ferromagnetic layers comprise NiFe.

11. The device according to claim 10, wherein the spacer comprises Ru.

12. A method, comprising:
forming a TMR element comprising a free layer, a spacer layer, and a reference layer,
forming the free layer by:
forming a first ferromagnetic layer to support a first vortex having a first chirality;
forming a second ferromagnetic layer to support a second vortex having a second chirality that is opposite the first chirality, wherein the first and second vortices are configured to be antiferromagnetically coupled; and
forming a spacer between the first and second ferromagnetic layers.

13. The method according to claim 12, wherein the first and second vortices move in opposite directions when an applied magnetic field is present.

14. The method according to claim 13, wherein the applied field is in plane.

15. The method according to claim 12, wherein the reference layer comprises first and second reference layers on opposite sides of the free layer.

16. The method according to claim 15, wherein the first and second reference layers are configured to share active junctions with the free layer.

17. The method according to claim 16, wherein the first and second reference layers are configured for insensitivity to an applied field.

18. The method according to claim 15, wherein the first and second reference layers are configured for sensitivity to an applied field.

19. The method according to claim 12, wherein a thickness of the spacer is configured to provide each magnetic moment of the first vortex is lying antiparallel to the second vortex in a same planar position.

20. The method according to claim 12, wherein the first ferromagnetic layer comprises NiFe.

21. The method according to claim 12, wherein the first and second ferromagnetic layers comprise NiFe.

22. The method according to claim 21, wherein the spacer comprises Ru.
